(19) United States
(12) Patent Application Publication
(10) Pub. No.: US 2009/0151997 A1
(43) Pub. Date: Jun. 18, 2009

(54) CIRCUIT BOARD

(75) Inventors: Hsiao-Yi Hsieh, Taipei (TW); Ren-Shuo Liu, Taipei (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: ALI CORPORATION, Taipei (TW)

(21) Appl. No.: 12/045,728

(22) Filed: Mar. 11, 2008

(30) Foreign Application Priority Data
Dec. 12, 2007 (CN) 200710194208.1

(51) Int. Cl. H05K 1/02

(52) U.S. Cl. 174/267

(57) ABSTRACT

An exemplary embodiment of a circuit board is provided. The circuit board is compatible to a first chip with a first pin number, and a second chip with a second pin number, comprising a plurality of first pads, second pads and third pads. The arrangements of the first and second pads are fit to the pin arrangement of the first chip, and the arrangements of the first and third pads are fit to the pin arrangement of the second chip. The first chip can be placed on the circuit board via the first and second pads, and the second chip can be placed on the circuit board via the first and third pads.

### CROSS REFERENCE TO RELATED APPLICATIONS

This application claims the benefit of China Application No. 200710194208.1, filed on Dec. 12, 2007.

### BACKGROUND OF THE INVENTION

1. Field of the Invention

The invention relates to circuit boards, and in particular, to a circuit board having compatibility to install different chips on the same area.

2. Description of the Related Art

System on Chip (SOC) is a kind of IC technology that integrates multiple functions in one chip. The size of an SOC may vary with the number of functionalities it contains, thus the number and arrangement of pins may also be different. Generally, an SOC is placed on a circuit board by welding or plugging, and is connected to other components through conducting wires of specific layouts. Functionalities of an end product made with an SOC may have various diversities, in which the circuit board may remain unmodified even if the SOC is a different version. Therefore, it is essential to design a circuit board having compatibility with many different SOCs.

Conventionally, additional pads and conducting wires are deployed in a circuit board to fit different SOCs, such that compatibility can be increased while area consumption is reduced. Related arts can be found in many publications and patents; however, a technical bottleneck has not yet been overcome. The bottleneck is the undesired effect induced by the additional conducting wires. As telecommunication systems continue to be developed, transmission quality of high-frequency signals or analog signals, for example, become more highly dependent on the impedances of the conducting wires. Although one circuit board may comprise more than two types of pads to provide compatibility to different SOCs, impedance mismatches or voltage drops may be induced by the conducting wires because paths are differed. It is therefore desirable to improve the present circuit board structure.

### BRIEF SUMMARY OF THE INVENTION

An exemplary embodiment of a circuit board is provided. The circuit board is compatible to a first chip with a first pin number, and a second chip with a second pin number, comprising a plurality of first pads, second pads and third pads. The arrangements of the first and second pads are fit to the pin arrangement of the first chip, and the arrangements of the first and third pads are fit to the pin arrangement of the second chip. The first chip is installed on the circuit board via the first and second pads, and the second chip is installed on the circuit board via the first and third pads.

The circuit board may be a printed circuit board (PCB). The total number of the first and second pads may be equal to the first pin number, and the total of the first and third pads may be equal to the second pin number. Some of the pads are floated if corresponding pins on the chips are absent. The first pads are used to conduct sensitive signals that are sensitive to resistance mismatch and interference, and the sensitive signals comprise high-frequency signals, analog signals, radio frequency signals, direct current voltage converter signals and oscillation signals. The second and third pads are used to conduct insensitive signals comprising low-frequency signals, digital signals and baseband signals.

The circuit board may further comprise a plurality of conducting wires coupling some of the second pads to some of the third pads. The spaces between any two adjacent pads among the first, second and third pads may be identical. The arrangements of the first and second pads are compliant to QFP64 standard, and the arrangements of the first and third pads are compliant to QFP100 standard. The circuit board is particularly suitable for a USB device, an FM receiver or a direct current voltage converter.

A further embodiment of a circuit board comprises a plurality of shared pads, having arrangements partially fit to the pin arrangements of the first and second chips for conducting sensitive signals that are sensitive to interferences, and a plurality of unshared pads, having arrangements fit to the rest of the pins of the first and second chips that are not fit to the shared pads. An area on the circuit board reserved for the first chip to be placed on is partially overlapped with an area reserved for the second chip.

The unshared pads comprise a first number of second pads, and a second number of third pads, the second pads are fit to the pins of the first chip that are not fit to the shared pads, and the third pads are fit to the pins of the second chip that are not fit to the shared pads. The shared pads are completely fit to all pins of the first chip, and are partially fit to some pins of the second chip, and the unshared pads comprise second number of third pads fit to the pins of the second chip that are not fit to the shared pads. Some of the shared pads and unshared pads are floated if corresponding pins on the chips are absent. The shared pads are used to conduct sensitive signals that are sensitive to impedance mismatch and interference, and the sensitive signals comprise high-frequency signals, analog signals, radio frequency signals, direct current voltage converter signals and oscillation signals. A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows an embodiment of a circuit board according to the invention;

FIG. 2a shows a first chip placed on the first footprint in FIG. 1;

FIG. 2b shows a second chip placed on the second footprint in FIG. 1;

FIG. 3 shows another embodiment of a circuit board;

FIG. 4 shows a further embodiment of a circuit board;

FIG. 5a shows a first chip 510 adaptable in the area 410 of FIG. 4;

FIG. 5b shows a second chip 520 adaptable in the areas 410 and 420 of FIG. 4;

FIG. 6 shows another embodiment of a circuit board;

FIG. 7a shows a first chip 700 adaptable in the first pads 612 and second pads 622 of FIG. 6; and

FIG. 7b shows a second chip 750 adaptable in the first pads 612 and third pads 632 of FIG. 6.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

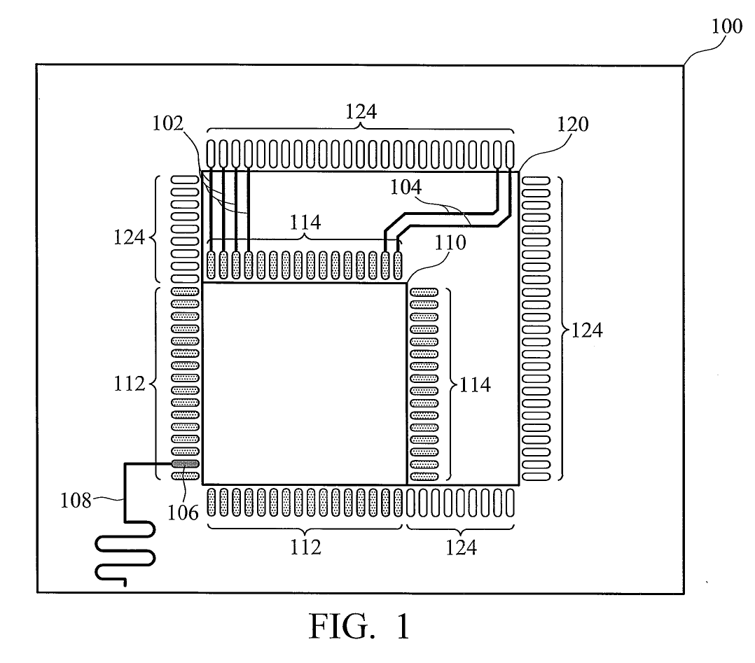

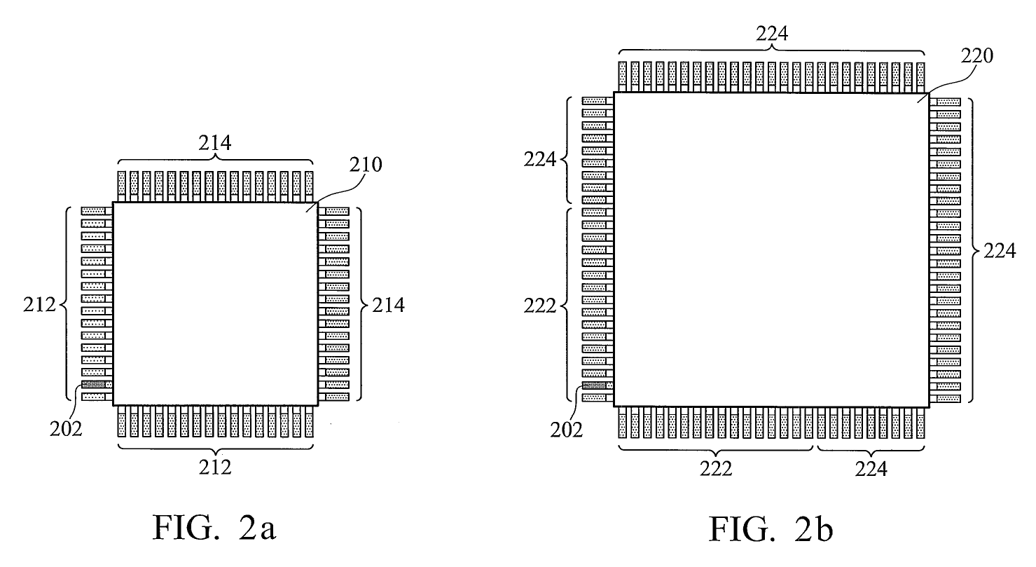

FIG. 1 shows an embodiment of a circuit board according to the invention. The circuit board 100 comprises two footprint, first footprint 110 and second footprint 120, partially overlapped at a same area, each compatible to a first chip 210 shown in FIG. 2a and a second chip 220 shown in FIG. 2b. The pads are categorized into shared pads and unshared pads. Specifically, there are three groups of pads, first pads 112, second pads 114 and third pads 124, with the first pads 112 as the shared pads. The first footprint 110 is formed by the first pads 112 and second pads 114, allowing the first chip 210 to be placed thereon. On the other hand, the second footprint 120 is formed from the first pads 112 and third pads 124, allowing the second chip 220 to be placed thereon. In this way, the first pads 112 show consistent wire lengths and impedances no matter what chip is selected to be installed on the circuit board 100, thus the quality of signal transmission can be retained. For this reason, the first pads 112 are particularly suitable for transmitting sensitive signals.

As to the first footprint 110 shown in FIG. 1, the arrangements of first pads 112 and second pads 114 constitute a square of 16 pads per edge, which matches the pin arrangement of first chip 210. And, the arrangements of first pads 112 and third pads 124 constitute a square of 25 pads per edge that matches the pin arrangement of second chip 220. Basically, the circuit board 100 is a printed circuit board (PCB), but the invention does not limit it. The pad arrangements may also be adapted to other circuit boards such as Low Temperature Coffered Ceramics (LTCC) substrates. As described, the first pads 112 (shared pads) of the embodiment are particularly suitable for transmitting sensitive signals that are sensitive to impedance mismatch or interferences. For example, high-frequency signals, analog signals, radio frequency signals, and direct current voltage converter signals are sensitive signals. High-frequency signals comprise USB, SATA, HDMI or DDR signals . . . etc. Radio frequency signals may comprise FM broadcast signals or oscillation sources. Some sensitive signal is sensitive to voltage drops, such as the Band Gap signals or power signals. Lengths, geometric shapes or relative positions of the conducting wires for these sensitive signals are possible causes for performance degradation, including interferences, impedance mismatches or voltage drops. In the embodiment, different SOCs use the same first pads 112 for transmitting the sensitive signals, so the problems caused by length difference, geometric shape difference and position difference are avoided. As an example, one pad 106 among the first pads 112 can be used to connect with an antenna 108 for transmitting radio frequency signals.

On the contrary, some insensitive signals may have less affection when the wire length is changed, so the second pads 114 and third pads 124 (unshared pads) are specifically used to transmit insensitive signals. The insensitive signals may comprise low-frequency signals, digital signals of high and low levels, and baseband signals.

The circuit board 100 may further comprise a certain number of conducting wires 102 or 104, designed to couple some of the second pads 114 to some of the third pads 124. The first chip 210 and second chip 220 may comprise different number of pins, however, some of the pins may be assigned with the same functionalities. The conducting wires 102 and 104, wire the pins of the same functionalities from the first footprint 110 to the second footprint 120, and their arrangement is not limited to what is shown in FIG. 1.

To provide compatibility, the spaces between any two adjacent pads among the first pads 112, second pads 114 and third pads 124 may be compliant to an identical standard. Likewise, the pin arrangements in the first chip 210 and second chip 220 also follow the same standard. The equal space between adjacent pins is not a limitation of the invention. The essential feature of the invention is the first pads 112 shared by the first chip 210 and the second chip 220 each placed on a corresponding first footprint 110 and second footprint 120.

FIG. 2a shows a first chip placed on the first footprint in FIG. 1. The first chip 210 comprises 64 pins arranged as a square of 16 pins per edge. Among which, pins 212 are associated to the first pads 112 in FIG. 1, and pins 214 are associated to the second pads 114. The pins and the pads may be welded or plugged. One of the pins 212 may be used to be an input port 202 associated with a pad 106 for receiving radio frequency signals received from the antenna 108. In a more flexible embodiment, not all 64 pins in the first chip 210 are required to couple a chip. If the pins in first chip 210 are less than 64 pins, or some of the pins have no connection, the first footprint 110 may still be adaptable to be coupled with the first chip 210. In other words, not all the first pads 112 or second pads 114 are necessarily required.

FIG. 2b shows a second chip placed on the second footprint in FIG. 1. The second chip 220 comprises 100 pins arranged as a square of 25 pins per edge. Among which, pins 222 are associated to the first pads 112 in FIG. 1, and pins 224 are associated to the third pads 124. Likewise, one of the pins 222 may be used to be an input/output (I/O) port 202 associated with a pad 106, for receiving sensitive radio frequency signals received from the antenna 108. The pins in second chip 220 may be less than 100 pins, or some of the pins may have no connection, so not all the first pads 112 or third pads 124 are necessarily required.

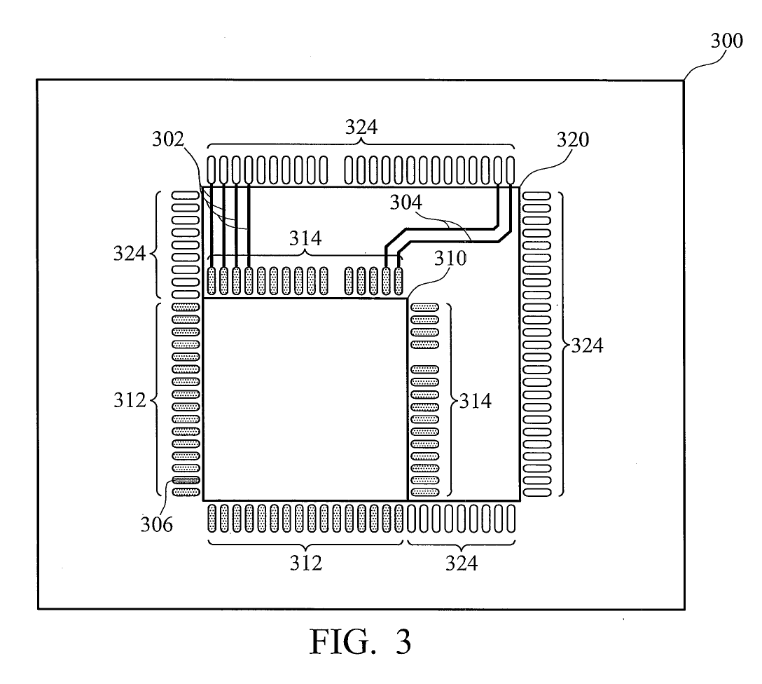

FIG. 3 shows another embodiment of a circuit board. In the circuit board 300, two footprints 310 and 320 are partially overlapped, and selectively adaptable to the first chip 210 in FIG. 2a and the second chip 220 in FIG. 2b. The design is similar to the embodiment in FIG. 1, and the difference is, some of the pads in 310 are absent. If the first chip 210 is coupled to the 310, some pins on the first chip 210 may be floated.

As to the second chip 220, if the some pads in the footprint 320 are absent or disabled, some pins on the second chip 220 are floated when coupled to the footprint 320. In this way, no matter whether the circuit board 300 is installed with the first chip 210 or second chip 220, conducting wires for the first pads 312 remain consistent lengths and impedances. So the first pads 312 are particularly adaptable for sensitive signals.

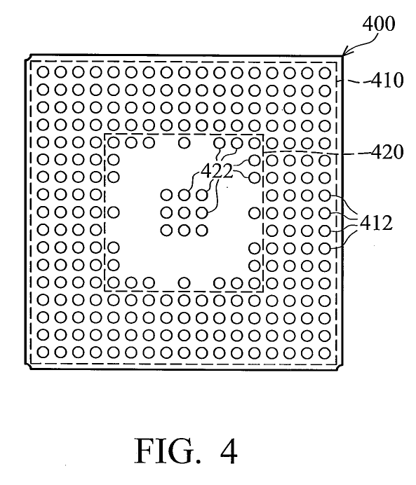

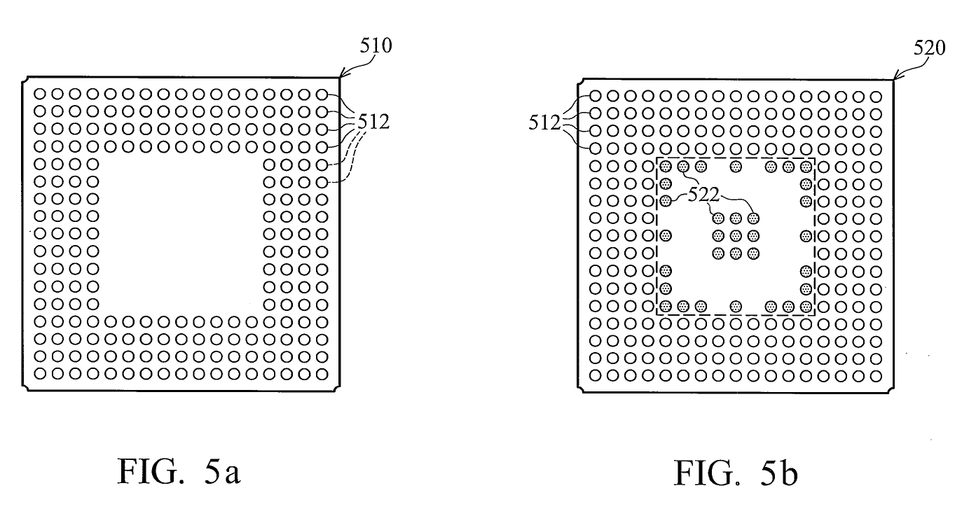

FIG. 4 shows a further embodiment of a circuit board. In the circuit board 400, two sets of pads are provided. The pads 412 are arranged within the area 410 but without the area 420, and the second pads 422 are arranged within the area 420. FIG. 5a shows a first chip 510 comprising a plurality of tin balls 512, and the arrangement of the tin balls 512 are fit to the arrangement of pads 412.

FIG. 5b shows a second chip 520 adaptable in the areas 410 and 420 of FIG. 4. The second chip 520 comprises the same plurality of tin balls 512 as the first chip 510, and additional tin balls 522 arranged in an inner area. When the second chip 520 is packaged on the circuit board 400, the tin balls 512 are fit to the pads 412, and the tin balls 522 are fit to the second pads 422. The first chip 510 may be compliant to PBGA208 standard, and the second chip 520 is PBGA241 standard. Since the pads 412 are shared by the two standards, they are suitable to conduct sensitive signals. On the contrary, the second pads 422 are used only when packaged with the second chip 520, so they are suitable to conduct insensitive signals.

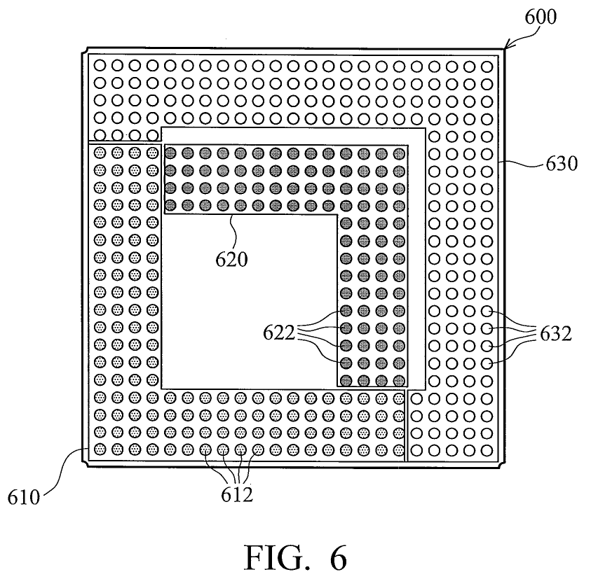

FIG. 6 shows another embodiment of a circuit board. The circuit board 600 comprises three areas first area 610, second area 620 and third area 630. The first pads 612 are placed in the first area 610, the second pads 622 are placed in second area 620, and the third pads 632 in third area 630.

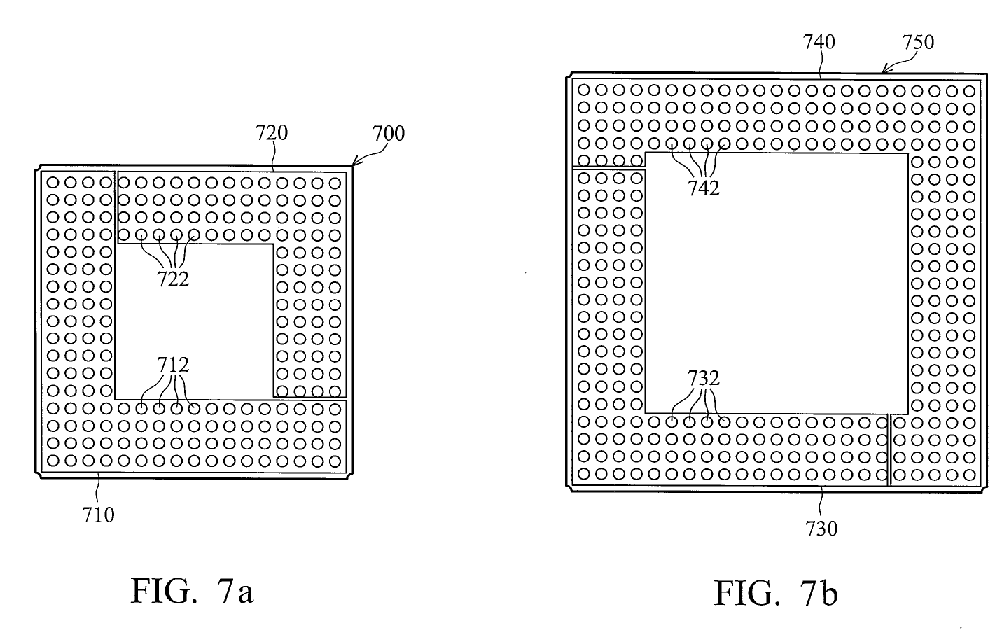

FIG. 7a shows a first chip 700 comprising a plurality of tin balls 712 and 722. The first tin balls 712 are placed in the first area 710, and the second tin balls 722 in the second area 720. The first area 710 is corresponding to the first area 610 in circuit board 600, and the second area 720 is corresponding to the second area 620. When the first chip 700 is packaged on the circuit board 600, the first tin balls 712 are respectively coupled to the first pads 612, and the second tin balls 722 fit the second pads 622.

FIG. 7b shows a second chip 750 comprising tin balls 732 and 742. The first tin balls 732 are placed in the first area 730, and the second tin balls 742 in the second area 740. The first area 730 is corresponding to the first area 610 in circuit board 600, and the second area 740 is corresponding to the third area 630 in circuit board 600. When the second chip 750 is packaged on the circuit board 600, the first tin balls 732 are coupled to the first pads 612, and the second tin balls 742 are coupled to the third pads 632. The first chip 700 in the embodiment may be compliant to PBGA208 standard, and the second chip 750 is PBGA304 standard. Since the first pads 612 are shared by the two standards, they are suitable to conduct sensitive signals. On the contrary, the second pads 622 and third pads 632 are accordingly used when packaged with different chips, so they are suitable to conduct insensitive signals.

The circuit boards described are particularly suitable for USB devices, FM receivers and direct current converter chips, and the invention is not limited thereto. The major concept is that the same plurality of pads on one circuit board is sharable for different chips, and the shared pads are used to transmit sensitive signals. Errors caused by impedance mismatches can be reduced because sensitive signals are not passed through additional conducting wires. In addition to SOCs, the invention is also suitable for system in package (SIP) chips. The SIP is an integrated circuit packaged with a plurality of chips.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A circuit board, compatible to a first chip with a first pin number, and a second chip with a second pin number, comprising:
a plurality of first pads;
a plurality of second pads; and
a plurality of third pads, wherein:
the arrangements of the first and second pads are fit to the pin arrangement of the first chip;
the arrangements of the first and third pads are fit to the pin arrangement of the second chip;
the first chip can be positioned on the circuit board via the first and second pads;and
the second chip can be positioned on the circuit board via the first and third pads.

2. The circuit board as claimed in claim 1, wherein the circuit board is a printed circuit board (PCB).

3. The circuit board as claimed in claim 1, wherein the total number of the first and second pads is equal to the first pin number, and the total number of the first and third pads is equal to the second pin number.

4. The circuit board as claimed in claim 1, wherein one of the pads is absent if corresponding pin on the chip has no connection.

5. The circuit board as claimed in claim 1, wherein the first pads are used to transmit sensitive signals that are sensitive to impedance mismatch and interference, and the sensitive signals comprise high-frequency signals, analog signals, radio frequency signals, direct current voltage converter signals and oscillation signals.

6. The circuit board as claimed in claim 1, wherein the second and third pads are used to conduct insensitive signals comprising low-frequency signals, digital signals and baseband signals.

7. The circuit board as claimed in claim 1, further comprising a conducting wire coupling one of the second pads to one of the third pads.

8. The circuit board as claimed in claim 1, wherein the spaces between any two adjacent pads among the first, second and third pads are identical.

9. The circuit board as claimed in claim 1, wherein the arrangements of the first and second pads are compliant to QFP64 standard.

10. The circuit board as claimed in claim 1, wherein the arrangements of the first and third pads are compliant to QFP100 standard.

11. The circuit board as claimed in claim 1, wherein the circuit board is employed in a USB device, an FM receiver or a direct current voltage converter.

12. A circuit board, compatible to a first chip with a first pin number and a second chip with a second pin number, comprising:
a plurality of shared pads, having arrangements partially fit to the pin arrangements of the first and second chips, for transmitting sensitive signals that are sensitive to interferences; and
a plurality of unshared pads, having arrangements fit to the rest of the pins of the first and second chips that are not fit to the shared pads,
wherein an area on the circuit board reserved for the first chip to be placed on is partially overlapped with an area reserved for the second chip.

13. The circuit board as claimed in claim 12, wherein:
the unshared pads comprise a first number of second pads, and a second number of third pads;
the second pads are fit to the pins of the first chip that are not fit to the shared pads; and
the third pads are fit to the pins of the second chip that are not fit to the shared pads.

14. The circuit board as claimed in claim 12, wherein:
the shared pads match all pins of the first chip and are partially fit to some pins of the second chip, and
the unshared pads comprise second number of third pads fit to the pins of the second chip that are not fit to the shared pads.

15. The circuit board as claimed in claim 12, wherein one of the pads are absent if corresponding pin on the chip has no connection.

16. The circuit board as claimed in claim 12, wherein the shared pads are used to transmit sensitive signals that are sensitive to impedance mismatch and interference, and the sensitive signals comprise high-frequency signals, analog signals, radio frequency signals, direct current voltage converter signals or oscillation signals.

17. The circuit board as claimed in claim 12, wherein the unshared pads are used to transmit insensitive signal comprising low-frequency signal, digital signal and baseband signal.

18. The circuit board as claimed in claim 12, wherein the circuit board is employed in a USB device, an FM receiver or a direct current voltage converter.
